(19) United States
(12) Patent Application Publication
(10) Pub. No.: US 2012/0257470 A1
(43) Pub. Date: Oct. 11, 2012

(54) MICROFLUIDIC MIXER

(75) Inventors: Julien Chapron, Bilston Glen (GB); Stuart Polwart, Bilston Glen (GB); Jonathan Salmon, Manila (PH)

(73) Assignee: ITI SCOTLAND LIMITED, Glasgow, GB (GB)

(21) Appl. No.: 13/501,885

(22) PCT Filed: Oct. 11, 2010
(86) PCT No.: PCT/EP2010/065226

§ 371 Date: Jun. 25, 2012

(30) Foreign Application Priority Data
Oct. 13, 2009 (GB) 0917919.3

(51) Int. Cl. B01F 15/02; B81B 1/00

(52) U.S. Cl. 366/262

(57) ABSTRACT

Provided is a microfluidic mixing system comprising a loop system for transferring one or more fluids, wherein the loop system comprises a plurality of sub loops, each sub loop formed from one or more common channels shared with at least one other sub loop and completed by an outer channel portion that is not shared by any other sub loop, and wherein the outer channel portion of each sub loop comprises one or more valves such that the sub loop is capable of isolation from all other sub loops and each common channel comprises one or more valves such that the common channel is capable of isolation from the remainder of the loop system, and wherein one or more sub loops in the system comprise valves that are configured to enable peristaltic mixing.

### FIELD OF THE INVENTION

The present invention concerns systems for mixing one or more fluids within a microfluidic device and methods for mixing fluids within a microfluidic device.

### BACKGROUND OF THE INVENTION

Microfluidic and nanofluidic devices are well known in the art, and are designed to manipulate fluids that are constrained in the microscale or nanoscale respectively. Microfluidic and nanofluidic devices have been used in many different fields which require the use of very small volumes of fluids, including engineering and biotechnology. For example, microfluidic systems have been used in the development of inkjet printheads and DNA chips.

Biological assays usually require various mixing steps. Quite often, successive mixing steps are required and in most methods known in the art it is necessary for a multistep reaction to include manual steps. For example, typical PCR reactions require the person carrying out the reaction to add reagents in multiple stages. Often reagents are either expensive or at low concentration, but the requirement of manual handling in known methods means that loss of analyte often occurs.

WO0281729 discloses a microfluidic device for nucleic acid amplification which comprises a peristaltic pump for transferring fluid. This document discloses a mixing loop comprising a peristaltic pump consisting of 3 valves for transferring fluids around the loop, resulting in mixing of the fluids. However, the pumping achieved with a 3 valve pump is not particularly efficient, and consequently fast and efficient mixing of fluids is not achieved. Furthermore this mixing loop does not enable multiple successive mixing steps to be achieved.

Accordingly, it is an aim of the present invention to solve one or more of the above-mentioned problems with the prior art. Specifically, it is an aim of the present invention to provide a microfluidic mixing system which allows for more efficient mixing of one or more fluids within a microfluidic device. It is desired that mixing occurs with minimal loss of any sample or reagents. It is also an aim of the present invention to provide a mixing system which allows for multiple successive mixing steps.

### STATEMENT OF INVENTION

Accordingly, the present invention provides a microfluidic mixing system comprising a loop system for transferring one or more fluids, wherein the loop system comprises one or more peristaltic pumps each comprising at least 4 valves which are capable of being opened and closed in sequence so as to enable peristaltic movement of the one or more fluids around the loop system in order to mix the fluids.

The microfluidic mixing system according to the present invention provides rapid and efficient mixing of one or more fluids. It has been found that pumping of the one or more fluids is significantly more efficient when 4 valves are used than when 3 valves are used.

In one embodiment the loop system comprises a single loop. The loop may comprise a plurality of channels for storing and/or transferring a plurality of fluids. This has the advantage that multiple fluids can be mixed within a single loop. Preferably, each channel comprises one or more valves such that the channel is capable of isolation from all other channels. In a most preferred embodiment the loop comprises four channels. Typically the loop is substantially square or rectangular and each channel provides a side of the square or rectangle.

The dimensions of the channels determine the volumes of the one or more fluids which will be mixed. This enables the volumes of reagents used in a reaction to be accurately metered.

In another embodiment the loop system comprises a plurality of sub loops, each sub loop formed from one or more common channels shared with at least one other sub loop and completed by an outer channel portion that is not shared by any other sub loop, and wherein the outer channel portion of each sub loop comprises one or more valves such that the sub loop is capable of isolation from all other sub loops and each common channel comprises one or more valves such that the common channel is capable of isolation from the remainder of the loop system.

In a further aspect, the present invention provides a microfluidic mixing system comprising a loop system for transferring one or more fluids, wherein the loop system comprises a plurality of sub loops, each sub loop formed from one or more common channels shared with at least one other sub loop and completed by an outer channel portion that is not shared by any other sub loop, and wherein the outer channel portion of each sub loop comprises one or more valves such that the sub loop is capable of isolation from all other sub loops and each common channel comprises one or more valves such that the common channel is capable of isolation from the remainder of the loop system. In this aspect of the invention the valves need not be peristaltic valves, although this is a preferred embodiment. If peristaltic valves are not used, any other suitable method may be used to transfer the one or more fluids around the loop system. For example any suitable pump may be employed.

The dimensions of the one or more common channels and the plurality of outer channel portions determine the volumes of the one or more fluids to be mixed.

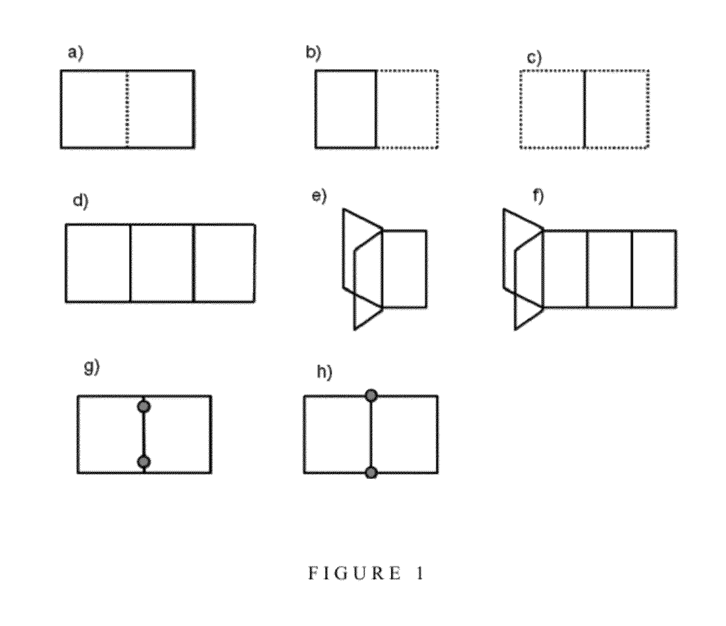

The loop system may comprise a plurality of common channels. In a preferred embodiment the loop system comprises n sub loops linked in series by n−1 common channels, wherein n is at least 2 (see FIG. 1d)). In a particularly preferred embodiment n=2.

It is also possible that a plurality of sub loops share a single common channel. In a preferred embodiment three sub loops share a single common channel (see FIG. 1e)).

In a particularly preferred embodiment, one or more sub loops in the system comprise valves that are configured to enable peristaltic mixing. Peristaltic mixing is achieved when the fluids to be mixed are transferred around the loop system by the peristaltic action of the valves opening and closing in sequence. When a valve in a sub loop is closed, positive displacement of the fluid ahead of the valve occurs, causing movement of the fluid around the loop. The mixing occurs thanks to dispersion, namely the flow is larger in the centre of the channel than on the edges of the channel.

Typically, each of the one or more sub loops configured to enable peristaltic mixing comprises 3 or more valves. It is more preferred that each of the one or more sub loops configured to enable peristaltic mixing comprises 4 or more valves.

It is also desirable that the microfluidic mixing system further comprises one or more inlets for delivering the one or more fluids to the loop system. In a preferred embodiment, each inlet comprises a valve capable of isolating the inlet.

The system may also further comprise one or more outlets for removing one or more fluids from the loop system. Preferably, each outlet comprises a valve capable of isolating the outlet.

The microfluidic mixing system may further comprise one or more chambers for storing, reacting or analysing one or more fluids. Typically, the system further comprises one or more valves capable of isolating the one or more chambers from the remainder of the loop system.

An outlet may be configured to deliver a fluid to be analysed from the loop system to both an analysis chamber and a control chamber.

In a preferred embodiment of the microfluidic mixing system, a sub loop comprises two valves in a common channel and one valve in the outer channel portion of the sub loop.

In one embodiment a valve is provided proximal to each end of a common channel (see FIG. 1g)). In another embodiment a valve is provided at each of the intersections of the common channel with the outer channel portion of the sub loop (see FIG. 1h)). It is preferable that a chamber is provided between the two valves.

It is also possible that a sub loop comprises one valve in a common channel and two valves in the outer channel portion of the sub loop.

A microfluidic mixing system preferably comprises a first sub loop and a second sub loop sharing a common channel, wherein the common channel comprises two valves and the outer channel portions of the first and second sub loops each comprise one valve.

In another preferred embodiment the system comprises a first sub loop, a second sub loop and a third sub loop which share a single common channel, and wherein a valve is provided at each of the two intersections of the common channel with the outer channel portions of the sub loops, and a further valve is situated in the common channel between the two valves at the intersections, the first sub loop comprises two valves in the outer channel portion and a chamber situated between the two valves in the outer channel portion, and the second and third sub loops each comprise one valve and one chamber. This mixing system enables three successive mixing steps to be carried out in an automated manner with no loss of sample or reagents.

Another aspect of the invention is provided by a method for mixing fluids in a microfluidic system, which method comprises filling a loop system with one or more fluids and subsequently opening and closing at least 4 valves in the loop system in sequence to enable peristaltic movement of the one or more fluids around the loop system. As discussed above, this method enables fast and efficient mixing of one or more fluids.

Preferably, the method involves the use of a loop system comprising at least 4 valves. Typically, the time period required to open or close a valve is in the range of 10 to 200 ms. Preferably, the time period required to open or close a valve is approximately 25 ms.

The method may use a loop system comprising a single loop. Preferably, the loop comprises a plurality of channels and each channel is filled with a fluid. Each channel may comprise at least one valve capable of isolating the channel from all other channels. Preferably, the loop comprises 4 channels. The loop may be substantially square or rectangular and in this case each channel provides a side of the square or rectangle.

In a preferred embodiment of the invention a first and second channel are filled with a first fluid, a third channel is filled with a second fluid and a fourth channel is filled with a third fluid and subsequently the at least 4 valves are opened and closed in sequence to enable the peristaltic movement of the 3 fluids around the loop in order to mix the 3 fluids. Preferably, the method comprises the further steps of:
a) removing a volume of the mixed solution from one of the channels and replacing this with a fourth fluid and;
b) opening and closing the at least 4 valves in sequence to enable the peristaltic movement of the fourth fluid and the remaining mixed solution in order to mix the fourth fluid with the mixed solution

This method enables two successive mixing steps to be carried out in a single loop with only minimal loss of reagent. For example, in a preferred embodiment only a quarter of the volume of the mixed solution is removed in step a).

A further aspect of the invention is provided by a method for mixing fluids in a microfluidic system, wherein the microfluidic system comprises a loop system for transferring one or more fluids, wherein the loop system comprises a plurality of sub loops, each sub loop formed from one or more common channels shared with at least one other sub loop and completed by an outer channel portion that is not shared by any other sub loop, and wherein the outer channel portion of each sub loop comprises one or more valves such that the sub loop is capable of isolation from all other sub loops and each common channel comprises one or more valves such that the common channel is capable of isolation from the remainder of the loop system, which method comprises the steps of:
a) filling one or more common channels with one or more fluids
b) filling two or more outer channel portions with one or more fluids
c) opening and closing the valves of at least one sub loop in a sequence which enables movement of one or more fluids around the at least one sub loop
d) opening and closing the valves of at least one further sub loop which shares one or more common channels with the sub loop of step c) to enable movement of one or more fluids around the at least one further sub loops
e) optionally repeating steps c) and d)

This method enables multiple successive mixing steps to be efficiently carried out in an automated manner without loss of fluid.

In a preferred embodiment of the method, the microfluidic system comprises a loop system comprising a first sub loop and a second sub loop sharing a single common channel, wherein the common channel comprises two valves and the outer channel portion of the first and second sub loops each comprise one valve, and the method comprises the steps of:
a) filling the common channel with a first fluid, filling the outer channel portion of the first sub loop with a second fluid and filling the outer channel portion of the second sub loop with a third fluid
b) opening and closing the three valves of the first sub loop in sequence so as to enable peristaltic movement of the first and second fluids around the first sub loop in order to mix the first and second fluids, wherein the valve in the outer channel portion of the second loop is closed
c) closing the valve in outer channel portion of the first sub loop and subsequently opening and closing the three valves of the second sub loop in sequence so as to enable peristaltic movement of the fluid mixture resulting from step b) and the third fluid around the second sub loop in order to mix the third fluid with the fluid resulting from step b)
d) optionally repeating steps b) and c)

This method allows two successive mixing steps to be carried out without loss of sample or reagent.

In another preferred embodiment of the method, the microfluidic system comprises a loop system comprising a first sub loop, a second sub loop and a third sub loop which share a single common channel, and wherein a valve is provided at each of the two intersections of the common channel with the outer channel portions of the sub loops, and a further valve is situated in the common channel between the two valves at the intersections, the first sub loop comprises two valves in the outer channel portion and a chamber situated between the two valves in the outer channel portion, and the second and third sub loops each comprise one valve and one chamber, and the method comprises the steps of:
a) filling the chamber of the third sub loop with a first fluid
b) filling the combined sub loop of the first and third sub loops with a second fluid
c) opening and closing the valves of the combined loop in sequence so as to enable peristaltic movement of the second fluid around the combined sub loop in order to mix the first fluid with the second fluid
d) filling the common channel with a third fluid
e) opening and closing the valves of third sub loop in sequence so as to enable peristaltic movement of the third fluid and the fluid mixture resulting from step c) around the third sub loop in order to mix the third fluid with fluid mixture resulting from step c)
f) filling the outer channel portion of the second sub loop with a fourth fluid
g) opening and closing the valves of the second and third sub loops in sequence so as to enable peristaltic movement of the fourth fluid and the fluid mixture resulting from step e) around the second and third sub loops in order to mix the fourth fluid with the fluid mixture resulting from step e)

This method allows three successive mixing steps to be carried out.

### DETAILED DESCRIPTION OF THE INVENTION

The present invention will now be described further by way of example only with reference to the accompanying figures, in which:

FIG. 1 shows schematics of the loop system architecture. FIG. 1a) shows a loop system comprising two sub loops sharing a single common channel (dotted line). FIG. 1b) shows the same loop system as in FIG. 1a) but here an outer channel portion is shown with a dotted line. A sub loop is shown with a continuous line. FIG. 1c) highlights a combined sub loop (dotted line). FIG. 1d) shows the arrangement wherein n sub loops are linked in series by n−1 common channels (n=3). FIG. 1e) shows the arrangement wherein three sub loops share a single common channel. FIG. 1f) shows an arrangement wherein three sub loops share a single common channel but additional sub loops are also provided in series. FIGS. 1g) and 1h) show the difference between a valve being provided proximal to each end of a common channel (FIG. 1g) and a valve being provided at each of the intersections of the common channel with the outer channel portion of the sub loop (FIG. 1h)).

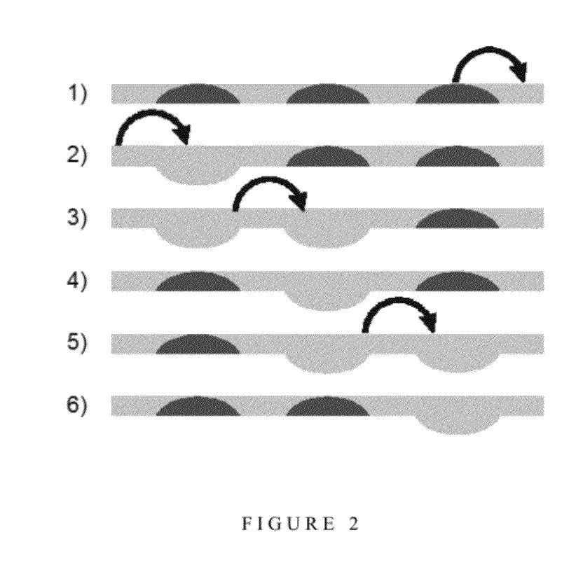

FIG. 2 is a schematic of the peristaltic cycle obtained from three valves in a row. Here is represented a microfluidic channel with three valves in row (represented in black when shut and grey when opened). A cycle made of six successive steps allows displacement of a volume of solution from left to right. When the sequence is continuously repeated, a net flow is obtained.

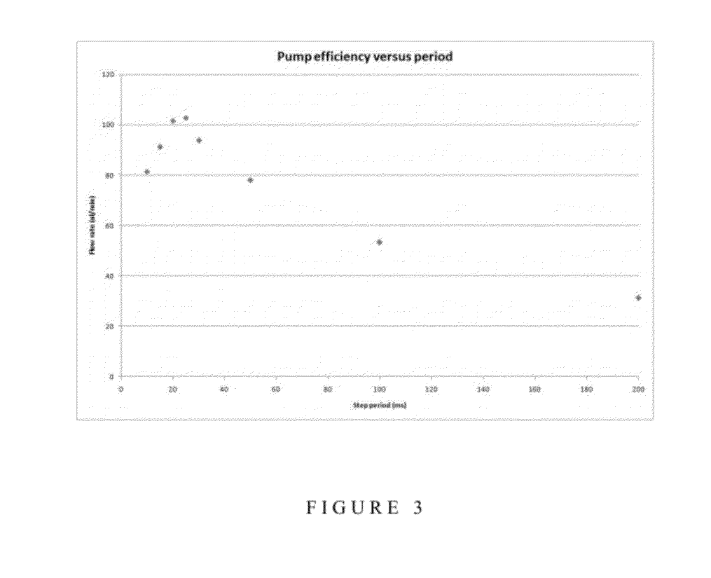

FIG. 3 shows a plot of fluid flow rate versus the time period between the steps in a peristaltic cycle.

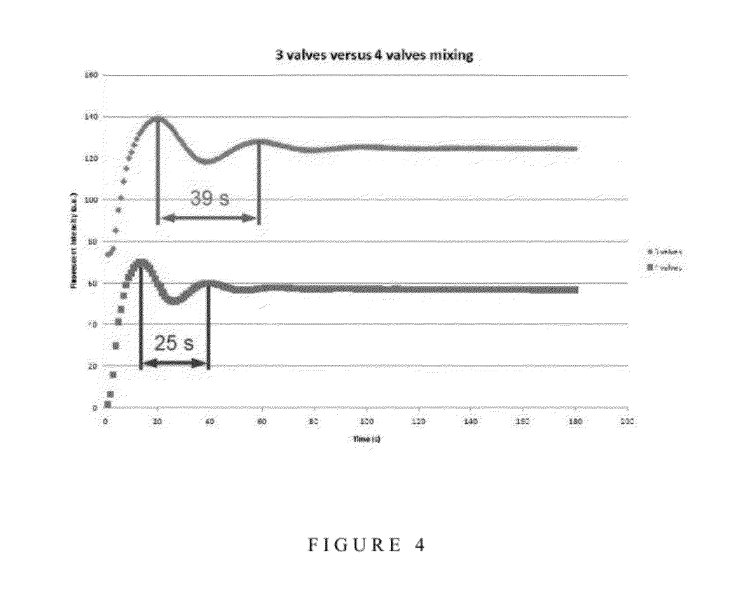

FIG. 4 shows a plot of fluorescence intensity versus time when fluorescein is mixed with water using a loop comprising 3 valves (diamonds) and 4 valves (squares).

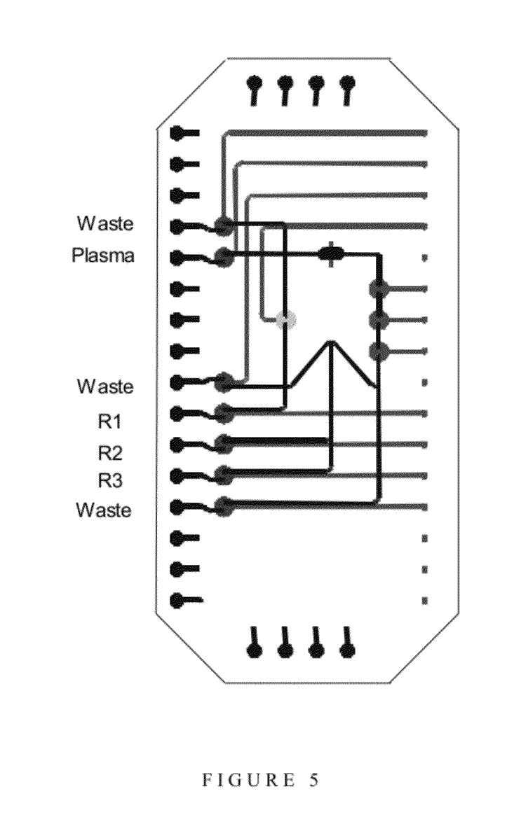

FIG. 5 shows a microfluidic device with a loop system comprising a single loop. The loop comprises 4 channels in a “square” where two sides are filled with sample, one with reagent 1 and the fourth side with reagent 2. The peristaltic pump comprising three valves (shown as circles in the right hand channel) is actuated to mix the solutions. Then the activator (reagent 3) is flown into the same fourth side of the square replacing a quarter of the premixed solution by reagent 3. These solutions are mixed again.

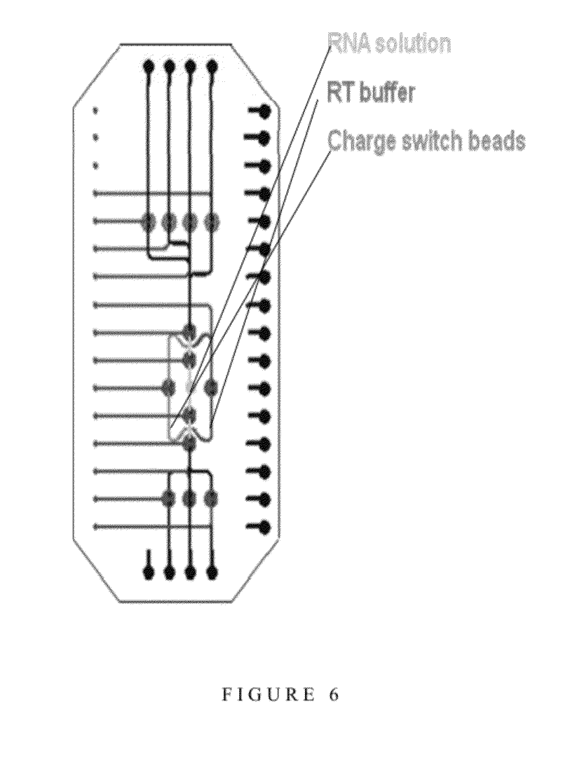

FIG. 6 shows a microfluidic device with a loop system comprising two sub loops sharing a common channel. The outer portion of the left sub loop is filled with charge switch beads, the common channel is filled with RNA solution and the outer portion of the right sub loop is filled with reverse transcription buffer. The microfluidic module is able to a) meter the RNA solution, RT buffer and charge switch beads, b) mix in a first step the RNA solution with the RT buffer and in a second step that first mix with the charge switch beads, c) meter out two identical volumes of the same solution to be analysed both in a sample chamber and in a control chamber. Valves are shown as large circles. A sample chamber is provided in the common channel (small circle).

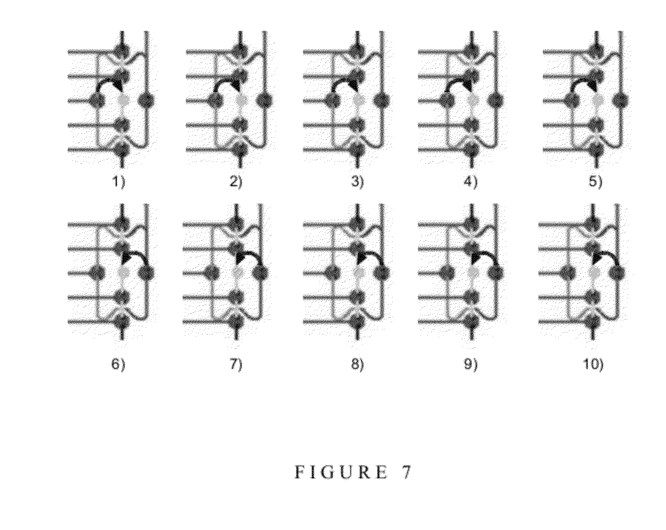

FIG. 7 shows the peristaltic sequence in a loop system comprising two sub loops sharing a common channel.

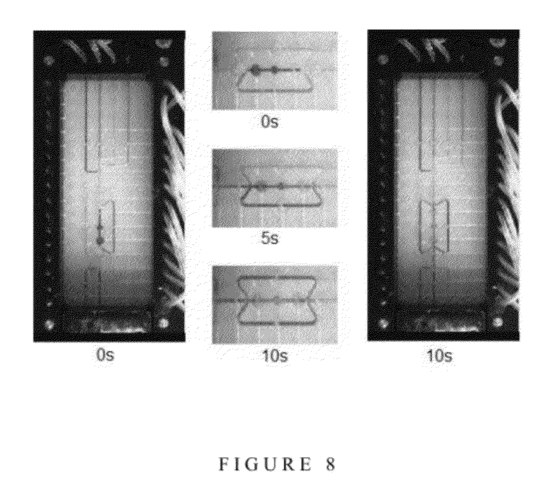

FIG. 8 shows photographs of the device shown in FIG. 6, this time used to mix a blue solution, a green solution and water (light grey, black and dark grey respectively at 0 s). 5 s after mixing the blue and green solutions have been mixed (see change of colour in the bottom sub loop). After 10 s all three solutions have been mixed, showing a uniform colour through the “figure of eight” of the loop system.

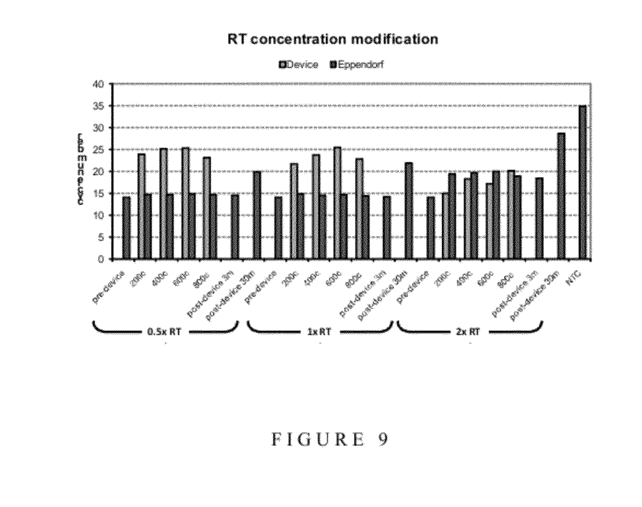

FIG. 9 shows the results of a comparison of reverse transcription carried out with the mixing system of the invention with standard reverse transcription carried out on the bench in an eppendorf at various enzyme concentrations. The cycle numbers refer to the readings from a quantitative PCR cycler. We can see that with 2× enzyme concentration, the reverse transcription on the chip of the invention compares nicely to the control obtained on the bench in an Eppendorf, confirming that reverse transcription reactions can be successfully carried out using the mixing system of the invention.

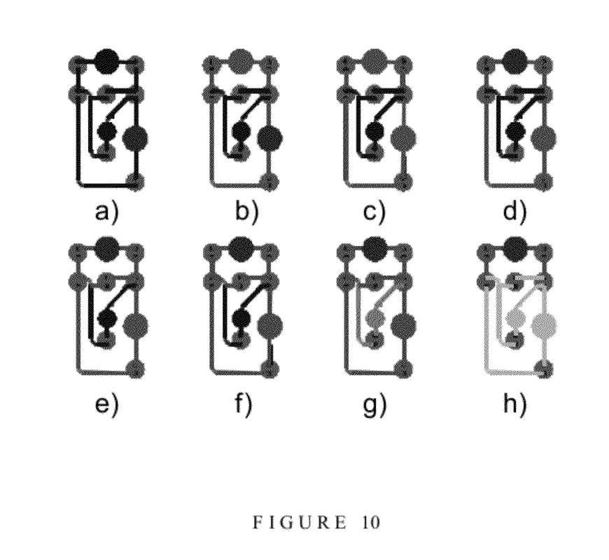

FIG. 10 shows a schematic of a 3 step mixing reaction carried out using a loop system comprising 3 sub loops sharing a single common channel.

A microfluidic mixing system is a system for mixing one or more fluids in the microscale. The system is for handling small volumes of liquid and typically comprises at least one channel having at least one dimension of less than 1 mm. Preferably the microfluidic mixing system is integral with a microfluidic device, such as a microfluidic chip. Alternatively, the microfluidic mixing system is a separate element in fluid connection with a microfluidic device.

One aspect of the invention provides a microfluidic mixing system comprising a loop system for transferring one or more fluids, wherein the loop system comprises one or more peristaltic pumps each comprising at least 4 valves which are capable of being opened and closed in sequence so as to enable peristaltic movement of the one or more fluids around the loop system in order to mix the fluids.

Peristaltic mixing is achieved when the fluids to be mixed are transferred around the loop system by the peristaltic action of the valves opening and closing in sequence. When a valve in the loop system is closed, positive displacement of the fluid ahead of the valve occurs, causing movement of the fluid around the loop. The mixing occurs thanks to dispersion, namely the flow is larger in the centre of the channel than on the edges of the channel.

FIG. 2 shows a schematic of the peristaltic cycle when 3 valves are used. An example of a sequence used with 3 valves can be described analogically with 1 for a valve closed and 0 for a valve opened (111,011,001,101,100,110). In the system of the invention at least 4 valves are provided in the peristaltic pump. In a preferred embodiment, 4 valves are used. When 4 valves are used, a similar sequence can be used (1111,0111,0011,0001,1001,1000,1100,1110), which comprises 8 steps. Other sequences of opening and closing valves may be used. All that is required is that the opening and closing of the valves achieves peristaltic movement of the fluid.

In one embodiment the loop system comprises a single loop. The loop may comprise a plurality of channels for storing and/or transferring a plurality of fluids. Preferably, each channel comprises one or more valves such that the channel is capable of isolation from all other channels. In a most preferred embodiment the loop comprises four channels. Typically the loop is substantially square or rectangular and each channel provides a side of the square or rectangle. The dimensions of the channels determine the volumes of the one or more fluids which will be mixed. In a preferred embodiment, two or more of the channels have the same dimensions so that the two or more channels each store the same volume of fluid.

Alternatively, the loop system comprises a plurality of sub loops, each sub loop formed from one or more common channels shared with at least one other sub loop and completed by an outer channel portion that is not shared by any other sub loop, and wherein the outer channel portion of each sub loop comprises one or more valves such that the sub loop is capable of isolation from all other sub loops and each common channel comprises one or more valves such that the common channel is capable of isolation from the remainder of the loop system.

A further aspect of the invention provides a microfluidic mixing system comprising a loop system for transferring one or more fluids, wherein the loop system comprises a plurality of sub loops, each sub loop formed from one or more common channels shared with at least one other sub loop and completed by an outer channel portion that is not shared by any other sub loop, and wherein the outer channel portion of each sub loop comprises one or more valves such that the sub loop is capable of isolation from all other sub loops and each common channel comprises one or more valves such that the common channel is capable of isolation from the remainder of the loop system.

The valves used in this aspect of the invention are not especially limited provided they are capable of isolating the relevant part of the loop system, for example a common channel or outer channel portion. It is not necessary for peristaltic valves to be used in this aspect of the invention, although this is a preferred embodiment. When a section of the loop system is “isolated” it means that no fluid can flow into or out of that section of the loop system.

A sub loop is defined as a loop within a loop system formed from one or more common channels completed by an outer channel portion that it not shared by any other sub loop in the loop system (see FIG. 1b)). A combined sub loop is defined as a loop within a loop system formed from the outer portions of two or more sub loops (see FIG. 1c)). A common channel is defined as a portion of the loop system shared by two or more sub loops in the loop system (see FIG. 1a)).

The outer channel portion of a sub loop is the portion of a single sub loop excluding the common channel (see FIG. 1b)). The outer channel portion is a channel which connects either end of a common channel to provide a loop. The shape of each sub loop is not especially limited; all that is required is that the sub loop provides a closed loop around which fluid can flow. In a preferred embodiment the common channel is substantially linear. Typically, the sub loop may be substantially square, rectangular or circular. The number of sub loops is not particularly limited provided more than one sub loop is present. Preferably, the loop system comprises 2 or 3 sub loops.

The dimensions of the one or more common channels and the plurality of outer channel portions determine the volumes of the one or more fluids to be mixed. For example, it may be desirable to provide a 2 step mixing procedure wherein 1 volume of a first fluid is mixed with 1 volume of a second fluid and then subsequently this premixed solution is mixed with 1 volume of a third fluid. In this case a loop system is provided wherein 2 sub loops share a common channel, and the two outer channel portions and the common channel are each designed to have dimensions to provide 3 equivalent volumes of fluid.

The microfluidic mixing system comprises a loop system for transferring one or more fluids. The term fluid is not especially limiting and each fluid may be any fluid to be used with a microfluidic or nanofluidic device. Examples include samples comprising one or more proteins, polypeptides, peptides, oligonucleotides, reagents, buffers, wash solutions, bead solutions or small molecules. In a particularly preferred embodiment the fluids are reagents required for a reverse transcription reaction. For example, the fluids may be a solution of RNA, a reverse transcription buffer and a solution of beads for capturing the cDNA.

The loop system may comprise a plurality of common channels. In a preferred embodiment the loop system comprises n sub loops linked in series by n−1 common channels, wherein n is at least 2 (see FIG. 1d)). Preferably, n is 2. In another embodiment the plurality of sub loops share a single common channel (see FIG. 1e)). In a preferred embodiment three sub loops share a single common channel. In a further embodiment the loop system comprises a plurality of sub loops linked in series by a number of common channels and additionally comprises a plurality of sub loops sharing a single common channel (see FIG. 1f)).

In a preferred embodiment each sub loop comprises 3 or more valves. In a more preferred embodiment, each sub loop comprises 4 or more valves. One, more or each sub loop may comprise 1 valve in the common channel and 2 valves in the outer channel portion. Alternatively, one, more or each sub loop may comprise 2 valves in the common channel and 1 valve in the outer channel portion of the sub loop. A valve may be provided proximal to each end of a common channel. By “proximal to each end of a common channel” it is meant that each valve is positioned near to an intersection of the common channel with the outer channel portion but is not actually located at the intersection (see the arrangement in FIG. 1g)). Alternatively, a valve may be provided at each of the intersections of the common channel with the outer channel portion of the sub loop (see FIG. 1h)). Preferably, a chamber is provided between the two valves proximal to each end of the common channel.

If the sub loop comprises 4 valves, the valves may be arranged with 3 valves situated in the common channel and 1 valve in the outer channel portion, 2 valves in the common channel and 2 valves in the outer channel portion or 1 valve in the common channel and 3 valves in the outer channel portion.

In a particularly preferred embodiment of the second aspect of the invention, one or more sub loops in the system comprise valves that are configured to enable peristaltic mixing. Peristaltic mixing is achieved when the fluids to be mixed are transferred around the loop system by the peristaltic action of the valves opening and closing in sequence. When a valve in a sub loop is closed, positive displacement of the fluid ahead of the valve occurs, causing movement of the fluid around the sub loop. The mixing occurs thanks to dispersion, namely the flow is larger in the centre of the channel than on the edges of the channel.

Typically, each of the one or more sub loops configured to enable peristaltic mixing comprises 3 or more valves. It is more preferred that each of the one or more sub loops configured to enable peristaltic mixing comprises 4 or more valves.

The microfluidic mixing system may further comprise one or more inlets for delivering the one or more fluids to the loop system. The arrangement of the one or more inlets is not especially limited; all that is required is that the one or more inlets are configured to deliver one or more fluids to the loop system. The one or more inlets may be in fluid connection with one or more fluid sources. The term fluid source is not especially limiting, and includes any source of fluid, including a continuous source of fluid. The fluid source may be a container containing the fluid. In this case the container may be any kind of container of any suitable size or shape. Typically, the fluid source is a chamber containing a fluid within a microfluidic device.

The microfluidic mixing system may further comprise one or more outlets for removing one or more fluids from the loop system. The arrangement of the one or more outlets is not especially limited; all that is required is that the one or more outlets are configured to remove one or more fluids from the loop system. The outlet may be for removing waste, for example used reagents or the by-products of a reaction. Alternatively, the outlet may be for removing a substance of interest, for example the product of a reaction or an analyte.

An outlet may be configured to deliver a fluid to be analysed from the loop system to both an analysis chamber and a control chamber.

In a preferred embodiment, each inlet comprises a valve capable of isolating the inlet. The architecture of the valve is not particularly limited; all that is required is that the valve is capable of isolating the inlet i.e. the valve is capable of preventing the flow of fluid into and out of the inlet.

Typically, each outlet comprises a valve capable of isolating the outlet. Again the architecture of the valve is not particularly limited and all that is required is that the valve is capable of isolating the outlet.

The microfluidic mixing system may further comprise one or more chambers for storing or reacting one or more fluids. The size and shape of the one or more chambers are not particularly limited. Preferably, the microfluidic mixing system comprises one or more valves capable of isolating the one or more chambers from the remainder of the loop system.

In a preferred embodiment, the microfluidic mixing system comprises a first sub loop and a second sub loop sharing a common channel, wherein the common channel comprises two valves, and the outer channel portions of the first and second sub loops each comprise one valve. A schematic of this embodiment is shown in FIG. 6.

In another embodiment, the microfluidic mixing system comprises a first sub loop, a second sub loop and a third sub loop which share a single common channel, and wherein a valve is provided at each of the two intersections of the common channel with the outer channel portions of the sub loops, and a further valve is situated in the common channel between the two valves at the intersections, the first sub loop comprises two valves in the outer channel portion and a chamber situated between the two valves in the outer channel portion, and the second and third sub loops each comprise one valve and one chamber. A schematic of this embodiment is shown in FIG. 10.

Another aspect of the invention provides a method for mixing fluids in a microfluidic system, which method comprises filling a loop system with one or more fluids and subsequently opening and closing at least 4 valves in the loop system in sequence to enable peristaltic movement of the one or more fluids around the loop system in order to mix the fluids. As discussed above, when a valve in the loop system is closed, positive displacement of the fluid ahead of the valve occurs, causing movement of the fluid around the loop. The mixing occurs thanks to dispersion, namely the flow is larger in the centre of the channel than on the edges of the channel.

Typically, the time period required to open or close a valve is in the range of 10 to 200 ms. Preferably, the time period required to open or close a valve is approximately 25 ms. It has been found that when the frequency of the steps in the peristaltic cycle is 25 ms an optimum flow rate is achieved (see FIG. 3).

The method may use a loop system comprising a single loop. Preferably, the loop comprises a plurality of channels for storing and/or transferring a plurality of fluids and each channel is filled with a fluid. The number of channels is not especially limited and will depend on the number of fluids to be mixed. Each channel may comprise one or more valves such that the channel is capable of isolation from all other channels. Preferably, the loop comprises 4 channels. The loop may be substantially square or rectangular and in this case each channel provides a side of the square or rectangle. However, it will be understood that the shape of the loop is not especially limited. All that is required is that a closed loop is provided around which fluid can flow.

In a preferred embodiment of the invention a first and second channel are filled with a first fluid, a third channel is filled with a second fluid and a fourth channel is filled with a third fluid and subsequently the at least 4 valves are opened and closed in sequence to enable the peristaltic movement of the 3 fluids around the loop in order to mix the 3 fluids. Preferably, the method comprises the further steps of:
a) removing a volume of the mixed solution from one of the channels and replacing this with a fourth fluid and;
b) opening and closing the at least 4 valves in sequence to enable the peristaltic movement of the fourth fluid and the remaining mixed solution in order to mix the fourth fluid with the mixed solution

In step a) a volume or aliquot of the mixed solution is removed from one of the channels. In a preferred embodiment, a quarter of the total volume of the mixed solution is removed. This may be achieved by connecting the channel to an outlet, and providing a valve at the intersection of the channel and the outlet. The valve can then be opened for a period of time sufficient for a volume of the mixed solution to leave the channel and pass into the outlet. The channel may also be provided with an inlet to replace the lost fluid with a fourth fluid. The flow of fluid into the channel from the inlet is preferably controlled by means of a valve.

In another embodiment each channel is filled with a different fluid. In a further embodiment a first and a second channel are filled with a first fluid and third and a fourth channel are filled with a second fluid.

FIG. 2 shows a schematic of the peristaltic cycle when 3 valves are used. An example of a sequence used with 3 valves can be described analogically with 1 for a valve closed and 0 for a valve opened (111,011,001,101,100,110). In the system of the invention at least 4 valves are provided in the peristaltic pump. In a preferred embodiment, 4 valves are used. When 4 valves are used, a similar sequence can be used (1111,0111,0011,0001,1001,1000,1100,1110), which comprises 8 steps. Other sequences of opening and closing valves may be used. All that is required is that the opening and closing of the valves achieves peristaltic movement of the fluid.

Also provided is a method for mixing fluids in a microfluidic system, wherein the microfluidic system comprises a loop system comprises a plurality of sub loops, each sub loop formed from one or more common channels shared with at least one other sub loop and completed by an outer channel portion that is not shared by any other sub loop, and wherein the outer channel portion of each sub loop comprises one or more valves such that the sub loop is capable of isolation from all other sub loops and each common channel comprises one or more valves such that the common channel is capable of isolation from the remainder of the loop system, which method comprises the steps of:
a) filling one or more common channels with one or more fluids
b) filling two or more outer channel portions with one or more fluids
c) opening and closing the valves of at least one sub loop in a sequence which enables movement of one or more fluids around the at least one sub loop
d) opening and closing the valves of at least one further sub loop which shares one or more common channels with the at least one sub loop of step c) to enable movement of one or more fluids around the at least one further sub loops
e) optionally repeating steps c) and d)

Steps c) and d) may be repeated as many times as desired. Typically steps c) and d) are repeated until thorough mixing of the fluids has been achieved. In a preferred embodiment steps c) and d) are repeated five times.

Preferably, the microfluidic system comprises a loop system comprising a first sub loop and a second sub loop sharing a single common channel, wherein the common channel comprises two valves and the outer channel portion of the first and second sub loops each comprise one valve, which method comprises the steps of:
a) filling the common channel with a first fluid, filling the outer channel portion of the first sub loop with a second fluid and filling the outer channel portion of the second sub loop with a third fluid
b) opening and closing the three valves of the first sub loop in sequence so as to enable peristaltic movement of the first and second fluids around the first sub loop in order to mix the first and second fluids, wherein the valve in the outer channel portion of the second loop is closed
c) closing the valve in outer channel portion of the first sub loop and subsequently opening and closing the three valves of the second sub loop in sequence so as to enable peristaltic movement of the fluid mixture resulting from step b) and the third fluid around the second sub loop in order to mix the third fluid with the fluid resulting from step b)
d) optionally repeating steps b) and c)

By causing peristaltic movement of the one or more fluids around the first loop and then peristaltic movement of the fluids around the second loop, this method allows the fluids to cycle in a “figure of eight”. Repeating this figure of eight cycle enables thorough mixing of the one or more fluids to be achieved. Preferably, steps b) and c) are repeated five times.

In an alternative embodiment, the microfluidic system comprises a loop system comprising a first sub loop, a second sub loop and a third sub loop which share a single common channel, and wherein a valve is provided at each of the two intersections of the common channel with the outer channel portions of the sub loops and a further valve is provided in between the two valves at the intersections, the first sub loop comprises two valves in the outer channel portion and a chamber situated in between the two valves in the outer channel portion, and the second and third sub loops each comprise one valve and one chamber, which method comprises the steps of:
a) filling the chamber of the third sub loop with a first fluid
b) filling the combined sub loop of the first and third sub loops with a second fluid
c) opening and closing the valves of the combined loop in sequence so as to enable peristaltic movement of the second fluid around the combined sub loop in order to mix the first fluid with the second fluid
d) filling the common channel with a third fluid
e) opening and closing the valves of third sub loop in sequence so as to enable peristaltic movement of the third fluid and the fluid mixture resulting from step c) around the third sub loop in order to mix the third fluid with fluid mixture resulting from step c)
f) filling the outer channel portion of the second sub loop with a fourth fluid
g) opening and closing the valves of the second and third sub loops in sequence so as to enable peristaltic movement of the fourth fluid and the fluid mixture resulting from step e) around the second and third sub loops in order to mix the fourth fluid with the fluid mixture resulting from step e).

In step g) of the method a “figure of eight” cycling of the fluid may be effected around the second and third sub loops, similarly to the previous embodiment.

### EXAMPLES

### Example 1

Effect of the Frequency of the Steps of the Peristaltic Cycle

Many biological assays require at least one mixing step. Most often, the mixing has to be quick to reduce the time to result (as in RNA assay). What is more is that certain enzymatic reactions might require the observation of a signal increase or decrease from a mixed solution. In this case, the mixing has to be very quick to allow the observation of the signal from the mixed solutions at rest (as in an alanine aminotransferase assay). As described above, the pumping may be done through actuation of three valves in a peristaltic cycle made of six steps. The frequency at which those steps follow each other will impact on the overall flow rate. FIG. 3 shows the effect of different time periods between successive steps ranging from 10 to 200 ms on the flow rate of the fluid. In the present invention, 25 ms provides the largest flow rate.

### Example 2

Use of a Four Valve Peristaltic Pump Rather than a Three Valve Peristaltic Pump Improves the Efficiency of Peristaltic Mixing

Once the three valve peristaltic pump had been optimised, it was discovered that the use of a fourth valve could make the pumping surprisingly more efficient. As described above, the sequence used with 3 valves can be described analogically with 1 for a valve closed and 0 for a valve opened (111,011,001,101,100,110). If four valves are used, a similar sequence can be used (1111,0111,0011,0001,1001,1000,1100,1110) which is made of 8 steps. Based on three valves, one volume is displaced in 6 steps whereas with 4 valves, there are 2 volumes that are displaced in 8 steps, which theoretically makes it 1.5 times more efficient (2×6/8).

The mixing of water with fluorescein was experimentally observed with a fluorescence microscope. Initially the signal is small when the window is located underneath the water channel, but the fluorescence signal quickly increases as the solutions turn into the mixing loop. The peak to peak values are characteristic of the time required to complete one turn of the loop. It was observed that whereas one revolution is completed in 39 seconds with three valves, it requires only 25 seconds with a fourth valve added which makes it 1.6 times more efficient (see FIG. 4).

### Example 3

Multiple Mixing Steps with a Single Loop Mixer

The ALT assay comprises a two step mixing procedure which is achieved using a loop which is a “square” where two sides are filled with sample, one with reagent 1 and the fourth side with reagent 2. The peristaltic pumps are actuated to mix the three solutions. Pyruvate is removed during this mixing step. Then the activator (reagent 3) is flown into the same fourth side of the square, replacing a quarter of the premixed solution by reagent 3. A further mixing step occurs and then fluorescent decay is measured. The metering of the fluids is achieved by providing channels of appropriate dimensions. The layout shown in FIG. 5 provides a saving in footprint and enables accurate metering. One advantage of this method is that although a portion of the sample is wasted, the waste is accurately controlled. With such a structure, it is easy to implement mixing steps of one volume of reagent 1 to one volume of reagent 2 to two volumes of sample. Then it is subsequently possible to mix one volume of reagent 3 with three volumes of the premixed solution.

### Example 4

Loop System Enabling Two Successive Mixing Steps

Reverse transcription requires accurate metering of the sample to the reverse transcription buffer. Then, a mixing step to mix the buffer with the sample is necessary. Once the transcription has taken place, it is advantageous to capture the cDNA on beads for further processing. Furthermore, the ability to split the mixture into two equal volumes for successive processing (if a control is required, i.e. PCR control) has been assessed. The microfluidic mixing system shown in FIG. 6 shows an embodiment where these various steps can be processed in a single microfluidic module with limited loss of target analytes. FIG. 6 shows the layout of a microfluidic device where a multiple ring mixer is used to capture cDNA on beads from an RNA solution. The microfluidic module is able to a) meter the RNA solution, RT buffer and charge switch beads, b) mix in a first step the RNA solution with the RT buffer and in a second step that first mix with the charge switch beads, c) meter out two identical volumes of the same solution to be analysed both in a sample chamber and in a control chamber.

The modified ring consists of two independent loops having a common channel. The three different channels forming that modified loop can be filled with RT buffer, RNA solution (sample) and a bead capture solution (i.e. charge switch). The volume of those channels will define the volume of solution.

First, three valves are used to create peristaltic cycles and pump the solutions within one individual ring comprising RT buffer and RNA solution. The reverse transcription takes place within that ring as the solutions get mixed. Then, the whole modified ring including the channel with capture beads is mixed with an eight pattern to capture the nucleic acid. Then, the left arm of the channel (which was originally filled with beads solution) can be flushed to further processing (say PCR). Then, independently, the right channel can be flushed (say to another PCR chamber). If the right channel and the left channel are equal in volumes, the volumes for further processing are equal making control possible.

The eight mixing pattern is obtained by flowing the solution from the external channel into the central channel. The peristaltic pump requires using three valves in a row in a peristaltic sequence. In that embodiment, the two valves from the central channel are used throughout the whole mixing and the third valve is either the left one (in the left channel) for a few successive cycles, or the right one (in the right channel) for the other cycles.

FIG. 7 shows the eight mixing pattern obtained from the loop system comprising two sub loops sharing a common channel. The pumping is obtained by repeating a peristaltic cycle made of six steps. The eight mixing profile is obtained by repeating successive cycles using three valves (2 in the common channel and one in the left arm) several times (5 times in the example) and then the same number of cycles is repeated with the two valves from the common channel and the one located in the right channel.

FIG. 8 shows photographs of the mixing system at different time periods after initiation of the mixing process. It can be seen in the left picture that the ring is filled with water on the left, blue solution in the centre, green solution on the right. In the first step, the blue and green solutions are mixed together, and in the second step, the mixed green solution and water are mixed to get a completely mixed solution.

Reverse transcription reactions can be carried out using this mixing system. The results of a comparison of reverse transcription carried out with the mixing system of the invention with standard reverse transcription carried out on the bench in an eppendorf at various enzyme concentrations are shown in FIG. 9. The cycle numbers refers to the reading from the quantitative PCR cycler. We can see that with 2× enzyme concentration, the reverse transcription on the chip of the invention compares nicely to the control obtained on the bench in eppendorf, confirming that reverse transcription reactions can be successfully carried out using the mixing system of the invention.

### Example 5

Loop System Enabling Three Successive Mixing Steps

In another embodiment of the invention, the loop system comprises three sub loops sharing a common channel. The idea here is to proceed to a) elution of RNA from Magmax beads b) reverse transcription c) cDNA capture on charge switch beads.

In this embodiment, the magmax beads (or any type of beads) are captured in the chamber in the right channel (a), brown chamber). Then the external ring is filled with the elution buffer (b) green channels). The external ring is turned using the three valves available to pump the solution into the external ring. The beads get mixed with the elution buffer (c) and get captured afterward in the top central chamber (d). The top part of that external ring with the trapped beads won't be used further. The reverse transcription buffer is then introduced into the top intermediate channel (e). The eluted RNA from the bottom part of the external mixer and the intermediate part containing the reverse transcription buffer get mixed (f). The charge switch beads are then introduced into the bottom intermediate channel (g) orange channel) and that channel gets mixed with the bottom part of the external mixer in a “figure of eight” as described in the previous embodiment (h).

1. A microfluidic mixing system comprising a loop system for transferring one or more fluids, wherein the loop system comprises a plurality of sub loops, each sub loop formed from one or more common channels shared with at least one other sub loop and completed by an outer channel portion that is not shared by any other sub loop, and wherein the outer channel portion of each sub loop comprises one or more valves such that the sub loop is capable of isolation from all other sub loops and each common channel comprises one or more valves such that the common channel is capable of isolation from the remainder of the loop system, and wherein one or more sub loops in the system comprise valves that are configured to enable peristaltic mixing.

2. A microfluidic mixing system according to claim 1, wherein the dimensions of the one or more common channels and the two or more outer channel portions determine the volumes of the one or more fluids to be mixed.

3. A microfluidic mixing system according to claim 1 or claim 2, wherein the loop system comprises a plurality of common channels.

4. A microfluidic mixing system according to any preceding claim, wherein the loop system comprises n sub loops linked in series by n−1 common channels, wherein n is at least 2.

5. A microfluidic mixing system according to claim 4 where n=2.

6. A microfluidic mixing system according to any preceding claim, wherein a plurality of sub loops share a single common channel,

7. A microfluidic mixing system according to claim 6 wherein three sub loops share a single common channel,

8. A microfluidic mixing system according to any preceding claim, wherein each of the one or more sub loops configured to enable peristaltic mixing comprises 3 or more valves.

9. A microfluidic mixing system according to claim 8 wherein each of the one or more sub loops configured to enable peristaltic mixing comprises 4 or more valves.

10. A microfluidic mixing system comprising a loop system for transferring one or more fluids, wherein the loop system comprises one or more peristaltic pumps each comprising at least 4 valves which are capable of being opened and closed in sequence so as to enable peristaltic movement of the one or more fluids around the loop system in order to mix the fluids, wherein the loop system comprises a single loop, and wherein the loop comprises a plurality of channels for storing and/or transferring a plurality of fluids.

11. A microfluidic mixing system according to claim 10, wherein each channel comprises one or more valves such that the channel is capable of isolation from all other channels.

12. A microfluidic mixing system according to claim 10 or claim 11 wherein the loop comprises four channels.

13. A microfluidic mixing system according to claim 12 wherein the loop is substantially square or rectangular and wherein each channel provides a side of the square or rectangle.

14. A microfluidic mixing system according to any of claims 10-13, wherein the dimensions of the channels determine the volumes of the one or more fluids to be mixed.

15. A microfluidic mixing system according to any preceding claim which further comprises one or more inlets for delivering the one or more fluids to the loop system.

16. A microfluidic mixing system according to claim 15 wherein each inlet comprises a valve capable of isolating the inlet.

17. A microfluidic mixing system according to any preceding claim which further comprises one or more outlets for removing one or more fluids from the loop system.

18. A microfluidic mixing system according to claim 17 wherein each outlet comprises a valve capable of isolating the outlet.

19. A microfluidic mixing system according to any preceding claim which further comprises one or more chambers for storing, reacting or analysing one or more fluids.

20. A microfluidic mixing system according to claim 19 wherein an outlet is configured to deliver a fluid to be analysed from the loop system to both an analysis chamber and a control chamber.

21. A microfluidic mixing system according to claim 19 or claim 20 which further comprises one or more valves capable of isolating the one or more chambers from the remainder of the loop system.

22. A microfluidic mixing system according to any preceding claim wherein one, more or each sub loop comprises two valves in the common channel and one valve in the outer channel portion of the sub loop.

23. A microfluidic mixing system according to any preceding claim wherein a valve is provided proximal to each end of a common channel.

24. A microfluidic mixing system according to claim 23 wherein a chamber is provided between the two valves proximal to each end of the common channel.

25. A microfluidic mixing system according to any of claims 1 to 22 wherein a valve is provided at each of the intersections of the common channel with the outer channel portion of the sub loop.

26. A microfluidic mixing system according to any of claims 1 to 21 wherein one, more or each sub loop comprises one valve in the common channel and two valves in the outer channel portion of the sub loop.

27. A microfluidic mixing system according to any of claims 1-25 which comprises a first sub loop and a second sub loop sharing a common channel, wherein the common channel comprises two valves and the outer channel portions of the first and second sub loops each comprise one valve.

28. A microfluidic mixing system according to any of claims 1-21 which comprises a first sub loop, a second sub loop and a third sub loop which share a single common channel, and wherein a valve is provided at each of the two intersections of the common channel with the outer channel portions of the sub loops, and a further valve is situated in the common channel between the two valves at the intersections, the first sub loop comprises two valves in the outer channel portion and a chamber situated in between the two valves in the outer channel portion, and the second and third sub loops each comprise one valve and one chamber.

29. A method for processing, transporting or mixing fluids in a micro- or nanofluidic system, which method employs a microfluidic mixing system as defined in any preceding claim.

30. A method for mixing fluids in a microfluidic system, which method comprises filling a loop system with one or more fluids and subsequently opening and closing at least 4 valves in the loop system in sequence to enable peristaltic movement of the one or more fluids around the loop system in order to mix the fluids.

31. A method according to claim 30, wherein the time period required to open or close a valve is in the range of 10 to 200 ms.

32. A method according to claim 31 wherein the time period required to open or close a valve is approximately 25 ms.

33. A method according to any of claims 30 to 32 wherein the loop system is a loop system as defined in any of claims 10 to 14.

34. A method according to claim 33 wherein a first and second channel are each filled with a first fluid, a third channel is filled with a second fluid and a fourth channel is filled with a third fluid and subsequently the at least 4 valves are opened and closed in sequence to enable the peristaltic movement of the 3 fluids around the loop in order to mix the 3 fluids.

35. A method according to claim 34, which comprises the further steps of
(c) removing a volume of the mixed solution from one of the channels and replacing this with a fourth fluid and;
(d) opening and closing the at least 4 valves in sequence to enable the peristaltic movement of the fourth fluid and the remaining mixed solution in order to mix the fourth fluid with the mixed solution.

36. A method for mixing fluids in a microfluidic system, wherein the microfluidic system is a system as defined in any of claims 1-9 and 15-28, which method comprises the steps of:
(a) filling one or more common channels with one or more fluids;
(b) filling two or more outer channel portions with one or more fluids;
(c) opening and closing the valves of at least one sub loop in a sequence which enables movement of one or more fluids around the at least one sub loop;
(d) opening and closing the valves of at least one further sub loop which shares one or more common channels with the sub loop of step c) in sequence to enable movement of one or more fluids around the at least one further sub loops;
(e) optionally repeating steps (c) and (d).

37. A method according to claim 36, wherein the microfluidic system comprises a loop system comprising a first sub loop and a second sub loop sharing a single common channel, wherein the common channel comprises two valves for isolating the common channel and the outer channel portion of the first and second sub loops each comprise one valve for isolating the sub loop, which method comprises the steps of:
(a) filling the common channel with a first fluid, filling the outer channel portion of the first sub loop with a second fluid and filling the outer channel portion of the second sub loop with a third fluid;
(b) opening and closing the three valves of the first sub loop in sequence so as to enable peristaltic movement of the first and second fluids around the first sub loop in order to mix the first and second fluids, wherein the valve in the outer channel portion of the second loop is closed;
(c) closing the valve in outer channel portion of the first sub loop and subsequently opening and closing the three valves of the second sub loop in sequence so as to enable peristaltic movement of the fluid mixture resulting from step b) and the third fluid around the second sub loop in order to mix the third fluid with the fluid mixture resulting from step b);
(d) optionally repeating steps b) and c).

38. A method according to claim 37, wherein the microfluidic system comprises a loop system comprising a first sub loop, a second sub loop and a third sub loop which share a single common channel, and wherein a valve is provided at each of the two intersections of the common channel with the outer channel portions of the sub loops and a further valve is provided in between the two valves at the intersections, the first sub loop comprises two valves in the outer channel portion and a chamber situated in between the two valves in the outer channel portion, and the second and third sub loops each comprise one valve and one chamber, which method comprises the steps of:
(a) filling the chamber of the third sub loop with a first fluid;
(b) filling the combined sub loop of the first and third sub loops with a second fluid;
(c) opening and closing the valves of the combined loop in sequence so as to enable peristaltic movement of the second fluid around the combined sub loop in order to mix the first fluid with the second fluid;
(d) filling the common channel with a third fluid;
(e) opening and closing the valves of third sub loop in sequence so as to enable peristaltic movement of the third fluid and the fluid mixture resulting from step c) around the third sub loop in order to mix the third fluid with fluid mixture resulting from step c);
(f) filling the outer channel portion of the second sub loop with a fourth fluid;
(g) opening and closing the valves of the second and third sub loops in sequence so as to enable peristaltic movement of the fourth fluid and the fluid mixture resulting from step e) around the second and third sub loops in order to mix the fourth fluid with the fluid mixture resulting from step e).
